(19) United States
(12) Patent Application Publication
(10) Pub. No.: US 2020/0278295 A1
(43) Pub. Date: Sep. 3, 2020

(54) Beam Pointing Monitor and Compensation Systems

(71) Applicant: ASML Holding N.V., Veldhoven (NL)

(72) Inventors: Matthew E. HANSEN, Milford, CT (US); Ronald A. WILKLOW, Fairfield, CT (US)

(73) Assignee: ASML Holding N.V., Veldhoven (NL)

(21) Appl. No.: 16/645,850

(22) PCT Filed: Sep. 4, 2018
(86) PCT No.: PCT/EP2018/073647

§ 371 Date: Mar. 10, 2020

Related U.S. Application Data
(60) Provisional application No. 62/557,253, filed on Sep. 12, 2017.

(51) Int. Cl. G01N 21/552; G02B 5/00; G03F 7/20; G01B 11/27

(52) U.S. Cl. CPC G01N 21/554; G02B 5/008; G01B 11/27; G03F 7/70258; G03F 7/7085; G03F 7/70141

(57) ABSTRACT

An optical system for beam pointing monitoring and compensation is provided. According to an embodiment, a beam pointing monitor and compensation system includes a surface plasmon resonance (SPR) optical element (800). The SPR optical element includes an optical element (801) that includes first (806) and second (802) surfaces. The first and second surfaces of the optical element are substantially parallel to each other. The SPR optical element further includes a first metal layer (803) provided on the second surface of the optical element, a dielectric layer (805) provided on the first metal layer, and a second metal layer (807) provided on the dielectric layer.

### CROSS-REFERENCE TO RELATED APPLICATIONS

This application claims priority of U.S. Provisional Patent Application No. 62/557,253, which was filed on Sep. 12, 2017, and which is incorporated herein in its entirety by reference.

### FIELD

Embodiments of the present disclosure relate to monitoring and compensation systems and methods for monitoring an angle of incidence of an optical beam and compensating for deviations, suitable for use as part of a lithographic apparatus.

### BACKGROUND

A lithographic apparatus is a machine that applies a desired pattern onto a substrate, usually onto a target portion of the substrate. A lithographic apparatus may be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

During lithographic operation, different processing steps may require different layers to be sequentially formed on the substrate. Accordingly, it may be necessary to position the substrate relative to prior patterns formed thereon with a high degree of accuracy. Generally, alignment marks, which may comprise diffraction gratings are placed on the substrate to be aligned and are located with reference to a second object. Lithographic apparatus may use an alignment system for detecting positions of the alignment marks and for aligning the substrate using the alignment marks to ensure accurate exposure from a mask.

In order to monitor the lithographic process, parameters of the patterned substrate are measured. Parameters may include, for example, the overlay error between successive layers formed in or on the patterned substrate and critical linewidth of developed photosensitive resist. This measurement may be performed on a product substrate and/or on a dedicated metrology target. There are various techniques for making measurements of the microscopic structures formed in lithographic processes, including the use of scanning electron microscopes and various specialized tools. A fast and non-invasive form of specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Illumination systems used in lithographic apparatuses, alignment systems, and/or scatterometers can include beam pointing sensors. However, most sensor designs fail to determine beam pointing variation with a precision that is desired.

### SUMMARY

In some embodiments of this disclosure, beam pointing monitor methods and systems are provided for more accurate beam pointing measurements. Additionally, in some embodiments of this disclosure, beam pointing compensation systems are provided to compensate for measured beam pointing variations.

According to an embodiment, a beam pointing monitor and compensation system includes a surface plasmon resonance (SPR) optical element. The SPR optical element includes an optical element that includes first and second surfaces. The first and second surfaces of the optical element are substantially parallel to each other. The SPR optical element further includes a first metal layer provided on the second surface of the optical element, a dielectric layer provided on the first metal layer, and a second metal layer provided on the dielectric layer.

In another embodiment, a system includes an illumination system configured to provide a radiation beam and a beam pointing monitor system. The beam pointing monitor system includes a surface plasmon resonance (SPR) optical element. The SPR optical element includes an optical element that includes first and second surfaces. The first and second surfaces of the optical element are substantially parallel to each other. The SPR optical element further includes a first metal layer provided on the second surface of the optical element, a dielectric layer provided on the first metal layer, and a second metal layer provided on the dielectric layer. The beam pointing monitor system is configured to measure an angle of incidence of the radiation beam with respect to a normal to the second surface of the optical element

Yet in another embodiment, a method includes illuminating, with a radiation beam, a surface plasmon resonance (SPR) optical element. The radiation beam is incident on the SPR optical element at an angle of incidence with respect to a normal to the SPR optical element. The SPR optical element comprises an optical element including first and second surfaces, where the first and second surfaces are substantially parallel to each other. The method also includes detecting, using a detector, a reflected radiation beam reflected from the SPR optical element. The SPR optical element provides a SPR of the reflected radiation beam. The method also includes measuring an intensity of the reflected radiation beam and determining the angle of incidence.

In another embodiment, an alignment system includes an illumination system configured to provide a radiation beam and a beam pointing monitor configured to measure an angle of incidence of the radiation beam with respect to a normal to a surface of the beam pointing monitor and configured to determine a beam pointing variation. The alignment system further includes a beam pointing compensator configured to receive a control signal based on the determined beam pointing variation and configured to adjust the angle of incidence of the radiation beam.

Yet in another embodiment, a lithographic apparatus includes a first illumination system configured to illuminate a pattern of a patterning device. The lithographic apparatus further includes a projection system configured to project an image of the pattern on to a target portion of a substrate. The lithographic apparatus also includes a system including a second illumination system configured to provide a radiation beam and a beam pointing monitor and compensation system. The beam pointing monitor and compensation system includes a surface plasmon resonance (SPR) optical element. The SPR optical element includes an optical element comprising first and second surfaces, a first metal layer provided on the second surface of the optical element, a dielectric layer provided on the first metal layer, and a second metal layer provided on the dielectric layer. The beam pointing monitor and compensation system is configured to measure an angle of incidence of the radiation beam with respect to a normal to the second surface of the optical element.

Further features and advantages of the disclosure, as well as the structure and operation of various embodiments of the disclosure, are described in detail below with reference to the accompanying drawings. It is noted that the disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the disclosure and to enable a person skilled in the relevant art(s) to make and use the invention.

FIG. 1A is a schematic illustration of a reflective lithographic apparatus according to an exemplary embodiment.

FIG. 1B is a schematic illustration of a transmissive lithographic apparatus according to an exemplary embodiment.

FIG. 2 is a more detailed schematic illustration of the reflective lithographic apparatus, according to an exemplary embodiment.

FIG. 3 is a schematic illustration of a lithographic cell, according to an exemplary embodiment.

FIGS. 4 and 5 are schematic illustrations of scatterometers, according to various exemplary embodiments.

FIG. 6 is a schematic illustration of an alignment system, according to an exemplary embodiment.

FIG. 7 is a schematic illustration of an exemplary beam pointing monitor and compensation system, according to an exemplary embodiment.

FIG. 8A-8C illustrate cross sections of an SPR optical element, according to various exemplary embodiments.

FIG. 9 schematically illustrates a plot of percent reflection as a function of incident angle, according to an exemplary embodiment.

FIG. 10 schematically illustrates a plot of percent reflection as a function of incident angle for a given wavelength of incident radiation beam, according to some embodiments.

FIGS. 11A and 11B illustrate exemplary SPR optical elements, according to various exemplary embodiments.

FIG. 11C illustrates a beam pointing monitor system, according to another exemplary embodiment.

FIGS. 12A-C illustrate exemplary beam pointing compensators, according to various exemplary embodiments.

FIG. 13 is a flowchart depicting a method for beam pointing monitor, according to an exemplary embodiment.

FIG. 14 is a flowchart depicting a method for beam pointing monitor and compensation, according to an exemplary embodiment.

Further features and advantages will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this disclosure. The disclosed embodiment(s) merely exemplify the disclosure. The scope of the disclosure is not limited to the disclosed embodiment(s). The disclosure is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure may be implemented.

### Example Reflective and Transmissive Lithographic Systems

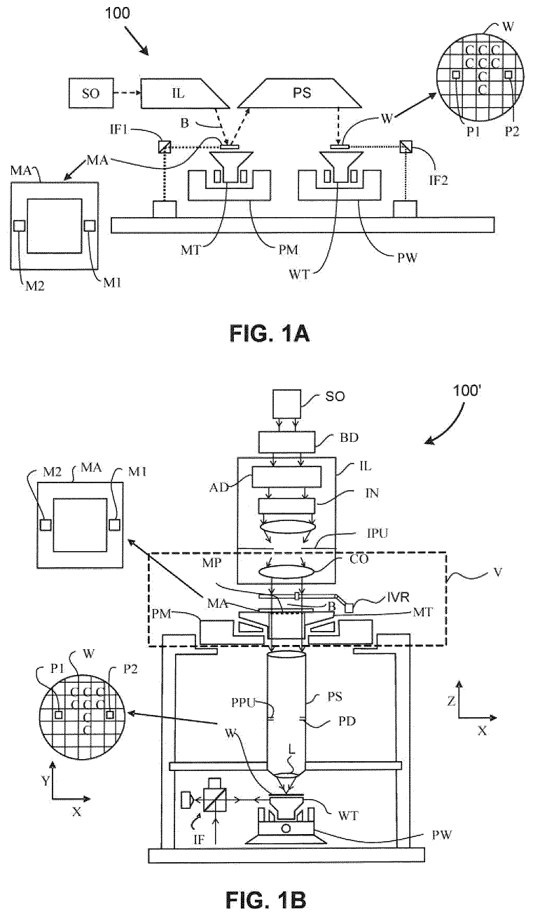

FIGS. 1A and 1B are schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, and programmable LCD panels. Masks are well known in lithography, and include mask types such as binary, alternating phase shift, and attenuated phase shift, as well as various hybrid mask types. An example of a programmable mirror array employs a matrix arrangement of small minors, each of which can be individually tilted so as to reflect an incoming radiation beam in different directions. The tilted minors impart a pattern in the radiation beam B which is reflected by a matrix of small minors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′—for example when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil PPU conjugate to an illumination system pupil IPU. Portions of radiation emanate from the intensity distribution at the illumination system pupil IPU and traverse a mask pattern without being affected by diffraction at a mask pattern and create an image of the intensity distribution at the illumination system pupil IPU.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ can be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

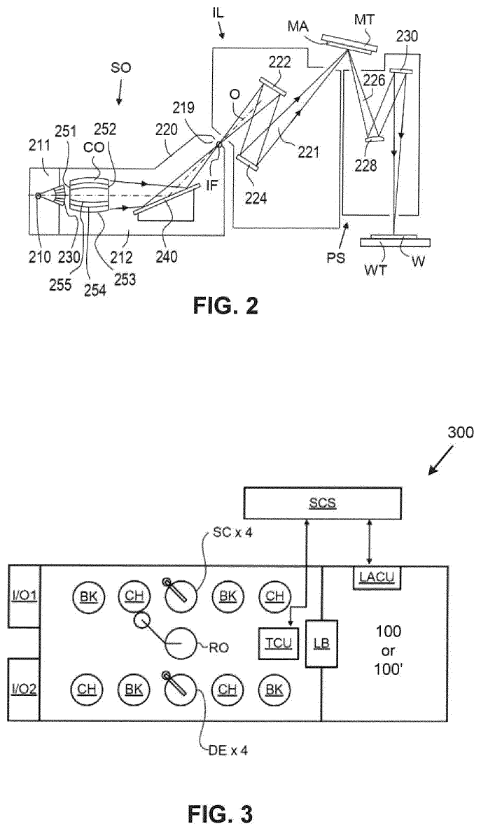

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a facetted field mirror device 222 and a facetted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 230 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be 1-6 additional reflective elements present in the projection system PS than shown in FIG. 2.

Collector optic CO, as illustrated in FIG. 2, is depicted as a nested collector with grazing incidence reflectors 253, 254 and 255, just as an example of a collector (or collector minor). The grazing incidence reflectors 253, 254 and 255 are disposed axially symmetric around an optical axis O and a collector optic CO of this type is preferably used in combination with a discharge produced plasma source, often called a DPP source.

### Example Lithographic Cell

FIG. 3 shows a lithographic cell 300, also sometimes referred to a lithocell or cluster. Lithographic apparatus 100 or 100′ may form part of lithographic cell 300. Lithographic cell 300 may also include apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

### Example Scatterometers

In order to ensure that the substrates that are exposed by a lithographic apparatus, such as lithographic apparatus 100 and/or 100′ are exposed correctly and consistently, it is desirable to inspect exposed substrates to measure properties such as overlay errors between subsequent layers, line thicknesses, critical dimensions (CD), etc. If errors are detected, adjustments may be made to exposures of subsequent substrates, especially if the inspection can be done soon and fast enough that other substrates of the same batch are still to be exposed. Also, already exposed substrates may be stripped and reworked—to improve yield—or discarded, thereby avoiding performing exposures on substrates that are known to be faulty. In a case where only some target portions of a substrate are faulty, further exposures can be performed only on those target portions which are good.

An inspection apparatus may be used to determine the properties of the substrates, and in particular, how the properties of different substrates or different layers of the same substrate vary from layer to layer. The inspection apparatus may be integrated into a lithographic apparatus, such as lithographic apparatus 100 and/or 100′ or lithocell 300 or may be a stand-alone device. To enable most rapid measurements, it is desirable that the inspection apparatus measure properties in the exposed resist layer immediately after the exposure. However, the latent image in the resist has a very low contrast—there is only a very small difference in refractive index between the parts of the resist which have been exposed to radiation and those which have not—and not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of faulty substrates but may still provide useful information.

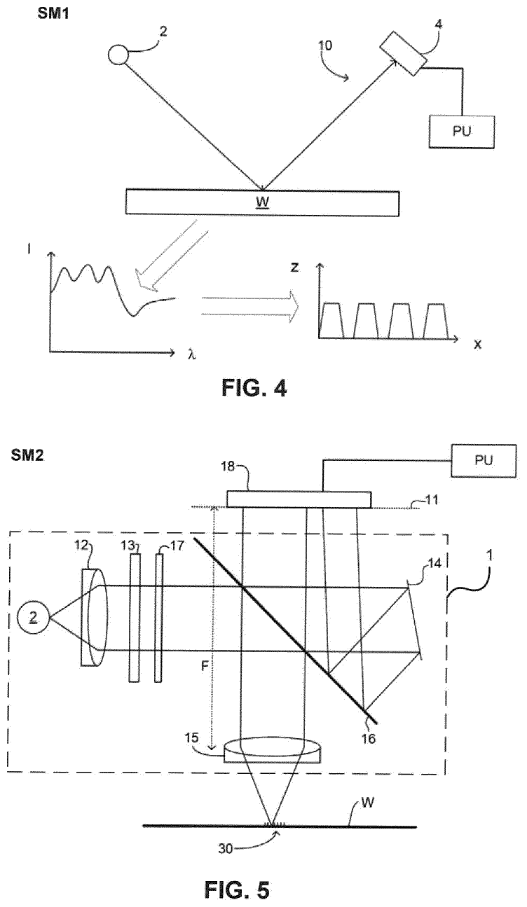

FIG. 4 depicts a scatterometer SM1 which may be used in the present disclosure. Scatterometer SM1 may be integrated into a lithographic apparatus, such as lithographic apparatus 100 and/or 100′ or lithocell 300 or may be a stand-alone device. It comprises a broadband (white light) radiation projector 2 which projects radiation onto a substrate W. The reflected radiation is passed to a spectrometer detector 4, which measures a spectrum 10 (intensity as a function of wavelength) of the specular reflected radiation. From this data, the structure or profile giving rise to the detected spectrum may be reconstructed by processing unit PU, e.g., by Rigorous Coupled Wave Analysis and non-linear regression or by comparison with a library of simulated spectra as shown at the bottom of FIG. 4. In general, for the reconstruction the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

Another scatterometer SM2 that may be used with the present disclosure is shown in FIG. 5. Scatterometer SM2 may be integrated into a lithographic apparatus, such as lithographic apparatus 100 and/or 100′ or lithocell 300 or may be a stand-alone device. Scatterometer SM2 may include an optical system 1 having a radiation source 2, a lens system 12, a filter 13 (e.g., interference filter), a reflecting device 14 (e.g., reference mirror), a lens system 15 (e.g., a microscopic objective lens system, also referred herein as objective lens system), a partially reflected surface 16 (e.g., a beam splitter), and a polarizer 17. Scatterometer SM2 may further include a detector 18 and a processing unit PU.

In one exemplary operation, the radiation emitted by radiation source 2 is collimated using lens system 12 and transmitted through interference filter 13 and polarizer 17, is reflected by partially reflected surface 16 and is focused onto substrate W via microscope objective lens system 15. The reflected radiation then transmits through partially reflecting surface 16 into a detector 18 in order to have the scatter spectrum detected. The detector may be located in the back-projected pupil plane 11, which is at the focal length of the objective lens system 15, however the pupil plane may instead be re-imaged with auxiliary optics (not shown) onto the detector. The pupil plane is the plane in which the radial position of radiation defines the angle of incidence and the angular position defines azimuth angle of the radiation. In one example, the detector is a two-dimensional detector so that a two-dimensional angular scatter spectrum of a substrate target 30 can be measured. The detector 18 may be, for example, an array of charge coupled device (CCD) or CMOS sensors, and may use an integration time of, for example, 40 milliseconds per frame.

A reference beam may be used, for example, to measure the intensity of the incident radiation. To do this, when the radiation beam is incident on beam splitter 16 part of it is transmitted through the beam splitter as a reference beam towards reference minor 14. The reference beam is then projected onto a different part of the same detector 18 or alternatively on to a different detector (not shown).

Interference filter 13 may include a set of interference filters, which may be available to select a wavelength of interest in the range of, say, 405-790 nm or even lower, such as 200-300 nm. The interference filter may be tunable rather than comprising a set of different filters. A grating could be used instead of interference filters.

Detector 18 may measure the intensity of scattered light at a single wavelength (or narrow wavelength range), the intensity separately at multiple wavelengths or integrated over a wavelength range. Furthermore, detector 18 may separately measure the intensity of transverse magnetic- and transverse electric-polarized light and/or the phase difference between the transverse magnetic- and transverse electric-polarized light.

Using a broadband light source (i.e., one with a wide range of light frequencies or wavelengths—and therefore of colors) for a radiation source 2 may give a large etendue, allowing the mixing of multiple wavelengths. The plurality of wavelengths in the broadband preferably each may have a bandwidth of Δλ and a spacing of at least 2 Δλ (i.e., twice the bandwidth). Several “sources” of radiation can be different portions of an extended radiation source which have been split using fiber bundles. In this way, angle resolved scatter spectra can be measured at multiple wavelengths in parallel. A 3-D spectrum (wavelength and two different angles) can be measured, which contains more information than a 2-D spectrum. This allows more information to be measured which increases metrology process robustness. This is described in more detail in EP1,628,164A, which is incorporated by reference herein in its entirety.

The target 30 on substrate W may be a 1-D grating, which is printed such that after development, the bars are formed of solid resist lines. The target 30 may be a 2-D grating, which is printed such that after development, the grating is formed of solid resist pillars or vias in the resist. The bars, pillars or vias may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. Accordingly, the scatterometry data of the printed gratings is used to reconstruct the gratings. The parameters of the 1-D grating, such as line widths and shapes, or parameters of the 2-D grating, such as pillar or via widths or lengths or shapes, may be input to the reconstruction process, performed by processing unit PU, from knowledge of the printing step and/or other scatterometry processes.

As described above, the target can be on the surface of the substrate. This target will often take the shape of a series of lines in a grating or substantially rectangular structures in a 2-D array. The purpose of rigorous optical diffraction theories in metrology is effectively the calculation of a diffraction spectrum that is reflected from the target. In other words, target shape information is obtained for CD (critical dimension) uniformity and overlay metrology. Overlay metrology is a measuring system in which the overlay of two targets is measured in order to determine whether two layers on a substrate are aligned or not. CD uniformity is simply a measurement of the uniformity of the grating on the spectrum to determine how the exposure system of the lithographic apparatus is functioning. Specifically, CD, or critical dimension, is the width of the object that is “written” on the substrate and is the limit at which a lithographic apparatus is physically able to write on a substrate.

### Alignment System with Beam Pointing Monitor and Compensation System According to an Embodiment

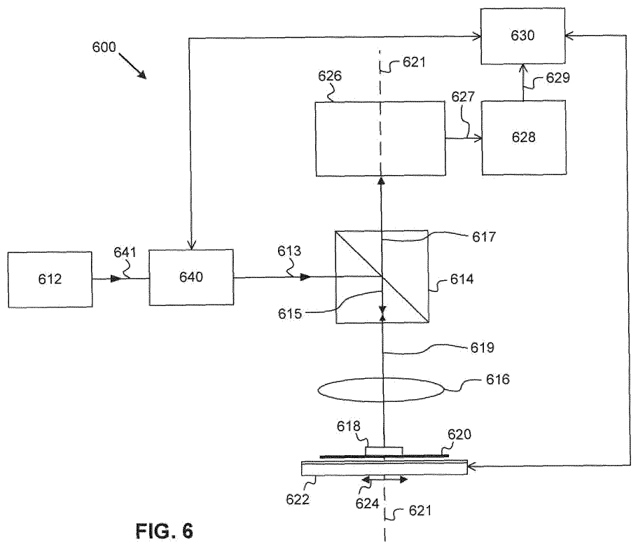

FIG. 6 illustrates a schematic illustration of an alignment system 600 that can be implemented as a part of lithographic apparatus 100 or 100′ and/or as part of scatterometers SM1 and SM2, according to an embodiment. In an example of this embodiment, alignment system 600 may be configured to align a substrate (e.g., substrate W) with respect to a patterning device (e.g., patterning device MA). Alignment system 600 may be further configured to detect positions of alignment marks on the substrate and to align the substrate with respect to the patterning device or other components of lithography apparatus 100 or 100′ using the detected positions of the alignment marks. Such alignment of the substrate may ensure accurate exposure of one or more patterns on the substrate.

According to an embodiment, alignment system 600 may include an illumination system 612, an optical system 614, an objective system 616, an image rotation interferometer 626, a detector 628, and a signal analyzer 630. Illumination system 612 may be configured to provide an electromagnetic narrow band radiation beam 641. In an example, the narrow band radiation beam 641 may be within a spectrum of wavelengths between about 500 nm to about 900 nm. In another example, the narrow band radiation beam 641 comprises discrete narrow passbands within a spectrum of wavelengths between about 500 nm to about 900 nm. Yet in another example, radiation beam 641 may be monochromatic, for example, provided by a monochromatic light source, such as a laser light source in illumination system 612. But polychromatic light sources such as LEDs may also be used in illumination system 612 to provide a polychromatic radiation beam 614. It is noted that radiation beam 614 is not limited to these examples and can include any suitable number and range of wavelengths.

According to some embodiments, alignment system 600 can further include a beam pointing monitor and compensation system 640 configured to determine beam pointing variation of a radiation beam with high accuracy and to compensate for the beam pointing variation. Beam pointing monitor and compensation system 640 can be configured to receive radiation beam 641, use a small portion of radiation beam 641 for beam pointing monitoring and compensation, and pass through radiation beam 613.

According to an embodiment, optical system 614 can include a beam splitter. Optical system 614 can be configured to receive radiation beam 613 and split radiation beam 613 into at least two radiation sub-beams, according an embodiment. In an example, radiation beam 613 can be split into radiation sub-beams 615 and 617, as shown in FIG. 6. Optical system 614 can be further configured to direct radiation sub-beam 615 onto a substrate 620 placed on a stage 622 moveable along direction 624. Radiation sub-beam 615 can be configured to illuminate an alignment mark or a target 618 located on substrate 620. Alignment mark or target 618 can be coated with a radiation sensitive film in an example of this embodiment. In another example, alignment mark or target 618 can have one hundred and eighty degree symmetry. That is, when alignment mark or target 618 is rotated one hundred and eighty degrees about an axis of symmetry perpendicular to a plane of alignment mark or target 618, rotated alignment mark or target 418 may be substantially identical to an unrotated alignment mark or target 618

As illustrated in FIG. 6, objective system 616 may be configured to direct diffracted radiation beam 619 towards image rotation interferometer 626, according to an embodiment. Objective system 616 may comprise any appropriate number of optical elements suitable for directing diffracted radiation beam 619. In an example embodiment, diffracted radiation beam 619 may be at least a portion of radiation beam 615 that is diffracted from alignment mark 618. It should be further noted that even though objective system 616 is shown to direct radiation beam 619 towards image rotation interferometer 626, the disclosure is not so limiting. It would be apparent to a person skilled in the relevant art that other optical arrangements may be used to obtain the similar result of detecting diffraction signals from alignment mark 618.

As illustrated in FIG. 6, image rotation interferometer 626 can be configured to receive radiation sub-beam 617 and diffracted radiation beam 619 through beam splitter 614. In an example of this embodiment, image rotation interferometer 626 can comprise any appropriate set of optical-elements, for example, a combination of prisms that may be configured to form two images of alignment mark 618 based on the received diffracted radiation beam 619. It should be appreciated that a good quality image need not be formed, but that the features of alignment mark 618 should be resolved. Image rotation interferometer 626 can be further configured to rotate one of the two images with respect to the other of the two images one hundred and eighty degrees and recombine the rotated and unrotated images interferometrically.

In an embodiment, detector 628 can be configured to receive the recombined image and detect an interference as a result of the recombined image when alignment axis 621 of alignment system 600 passes through a center of symmetry (not shown) of alignment mark 618. Such interference may be due to alignment mark 618 being one hundred and eighty degree symmetrical, and the recombined image interfering constructively or destructively, according to an example embodiment. Based on the detected interference, detector 628 can be further configured to determine a position of the center of symmetry of alignment mark 618 and consequently, detect a position of substrate 620. According to an example, alignment axis 621 can be aligned with an optical beam perpendicular to substrate 620 and passing through a center of image rotation interferometer 626.

In a further embodiment, signal analyzer 630 can be configured to receive signal 629 including information of the determined center of symmetry. Signal analyzer 630 can be further configured to determine a position of stage 622 and correlate the position of stage 622 with the position of the center of symmetry of alignment mark 618. As such, the position of alignment mark 618 and consequently, the position of substrate 620 can be accurately known with reference to stage 622. Alternatively, signal analyzer 630 can be configured to determine a position of alignment system 600 or any other reference element such that the center of symmetry of alignment mark 618 may be known with reference to alignment system 600 or any other reference element.

According to some examples, signal analyzer 630 can include one or more processing units, computing devices, processors, controllers, or other devices executing a firmware, software, routines, instructions, etc. to implement one or more embodiments of this disclosure.

It should be noted that even though a beam splitter 614 is shown to direct radiation beam 615 towards alignment mark or target 618 and to direct reflected radiation beam 619 towards image rotation interferometer 626, the disclosure is not so limiting. It would be apparent to a person skilled in the relevant art that other optical arrangements may be used to obtain the similar result of illuminating alignment mark or target 618 on substrate 620 and detecting an image of alignment mark or target 618.

According to some embodiments, alignment system 600 can further include the beam pointing monitor and compensation system 640. It is noted that although beam pointing monitor and compensation system 640 is discussed in accordance with alignment system 600, the beam pointing monitor and compensation system 640 can be part of lithographic apparatus 100, lithographic apparatus 100′, scatterometer SM1, scatterometer SM2, or any other apparatus to determine beam pointing variation of a radiation beam with high accuracy and to compensate for the beam pointing variation. For example, beam pointing monitor and compensation system 640 can be used with an illumination system used in apparatus 100, lithographic apparatus 100′, scatterometer SM1, scatterometer SM2, alignment system 600, or any other apparatus.

Also, it is noted that although FIG. 6 illustrates the beam pointing monitor and compensation system 640 to be located between illumination system 612 and optical system 614, the beam pointing monitor and compensation system 640 can be located at other places on the optical path within alignment system 600 or other systems. For example, the beam pointing monitor and compensation system 640 can be part of illumination system 612. As another example, other optical elements (such as, but not limited to relay lenses, prisms, field stops, etc.) can be provided between illumination system 612 and optical system 614, and the beam pointing monitor and compensation system 640 can provided within these optical elements. Also, as discussed in more detail below, the beam pointing monitor and compensation system 640 can be based on and use the optical elements already used within alignment system 600 or other systems where the beam pointing monitor and compensation system 640 is being used.

According to some examples, beam pointing monitor and compensation system 640 is configured to receive radiation beam 641 from illumination system 612. Beam pointing monitor and compensation system 640 can use a small portion of radiation beam 641 to measure beam pointing deviation and compensate for any deviation. According to some embodiments, beam pointing monitor and compensation system 640 can be coupled with signal analyzer 630. In this example, beam pointing monitor and compensation system 640 can send a measured intensity of the radiation beam, a measured incident angle of the radiation beam, and/or a measured beam pointing deviation to signal analyzer 630. Signal analyzer 630 can analyze the measured intensity of the radiation beam, the measured incident angle of the radiation beam, and/or the measured beam pointing deviation and send control signals to beam pointing monitor and compensation system 640 to compensate for any deviation.

For example, signal analyzer 630 can receive a measured intensity of a radiation beam from beam pointing monitor and compensation system 640, determine the incident angle of the radiation beam, compare the determined incident angle with a reference beam angle, determine the beam pointing deviation, and generate a control signal based on the determined beam pointing deviation. Signal analyzer 630 can send the control signal to beam pointing monitor and compensation system 640 to compensate for the measured deviation. According to some examples, beam pointing monitor and compensation system 640 can be configured to measure an angle of incidence and/or variations in an angle of incidence in the range of pico-radian.

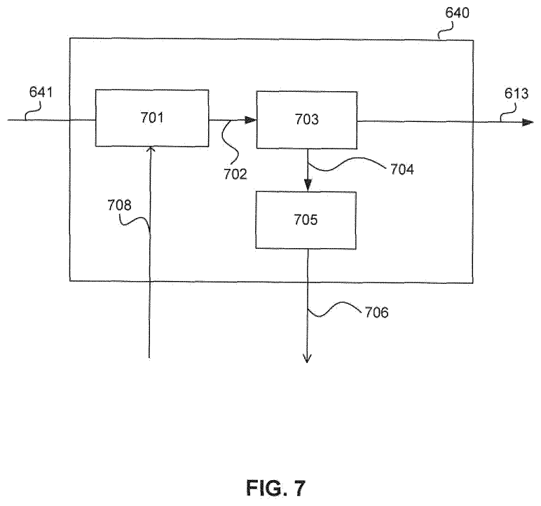

FIG. 7 illustrates an exemplary beam pointing monitor and compensation system 640 according to some embodiments. In this example, beam pointing monitor and compensation system 640 can include a beam pointing compensator 701 and a beam pointing monitor system including a surface plasmon resonance (SPR) optical element 703 and an optical detector 705. As noted above, beam pointing compensator 701, surface plasmon resonance (SPR) optical element 703, and/or optical detector 705 can be (and/or use) the optical elements already used in alignment system 600 or any other systems with which beam pointing monitor and compensation system 640 is being used.

According to some embodiments, beam pointing compensator 701 is configured to receive radiation beam 641 from, for example, illumination system 612 of FIG. 6. Beam pointing compensator 701 can also be configured to receive a control signal 708 from signal analyzer 630 of FIG. 6. Depending on the control signal 708, beam pointing compensator 701 can be configured to adjust radiation beam 641 to compensate for any measured beam pointing deviations.

The beam pointing monitor and compensation system 640 can use a surface plasmon resonance (SPR) optical element (such as SPR optical element 703) to direct a radiation beam to optical detector 705. The beam pointing monitor and compensation system 604 can utilize SPR effects to measure beam pointing deviation for calibration and correction purposes. SPR can be characterized by a loss of reflected intensity from a surface because of resonant absorption of light due to surface plasmon (SP) excitation. SPR optical element 703 is configured to receive radiation beam 702 from beam pointing compensator 701, and use a small portion of radiation beam 702 for beam pointing measurement. Most of received radiation beam 702 can be transmitted as radiation beam 613. Radiation beam 613 can be used, for example, in alignment system 600, as discussed above, for alignment measurements. However, as noted above, radiation beam 613 can also be used in other systems such as lithographic apparatus 100, lithographic apparatus 100′, scatterometer SM1, scatterometer SM2, or any other apparatus.

According to some embodiments, SPR optical element 703 can include another optical element configured to receive radiation beam 702 and pick off some portion of the radiation beam 702 for beam pointing monitor and compensation. Additionally or alternatively, the other optical element to pick off some portion of the radiation beam 702 for beam pointing monitor and compensation is not part of SPR optical element 703 but can be located between beam pointing compensator 701 and SPR optical element 703. According to some examples, the optical element used to pick off some portion of the radiation beam 702 for beam pointing monitor and compensation can include a minor, a prism, a beam splitter, or any other suitable optical element.

According to some embodiments, the portion of radiation beam 702 that is picked off for beam pointing monitor and compensation can include a portion of radiation beam 702 that is not used in alignment system 600 (or other systems where the beam pointing monitor and compensation system 640 is being used.) In one example, the portion of radiation beam 702 that is picked off for beam pointing monitor and compensation can include a radiation beam with S polarization orientation.

According to some embodiments, SPR optical element 703 can be configured to reflect radiation 704 from a small portion of radiation 702 that SPR optical element 703 has received. SPR optical element 703 can direct radiation beam 704 to optical detector 705 for measuring the intensity of radiation beam 704 and therefore, the beam pointing of radiation beam 702. According to some examples, optical detector 705 can send the measured intensity and/or beam pointing 706 to, for example, signal analyzer 630 of FIG. 6 for further analysis and also for generating control signal 708 used for beam pointing compensation.

According to some examples, SPR optical element 703 can also be controlled by, for example, signal analyzer 630. For example, in addition to or alternate to controlling beam pointing compensator 701, signal analyzer 630 can send control signals to SPR optical element 703 to move SPR optical element 703 based on the measured beam angle and/or measured beam pointing variations.

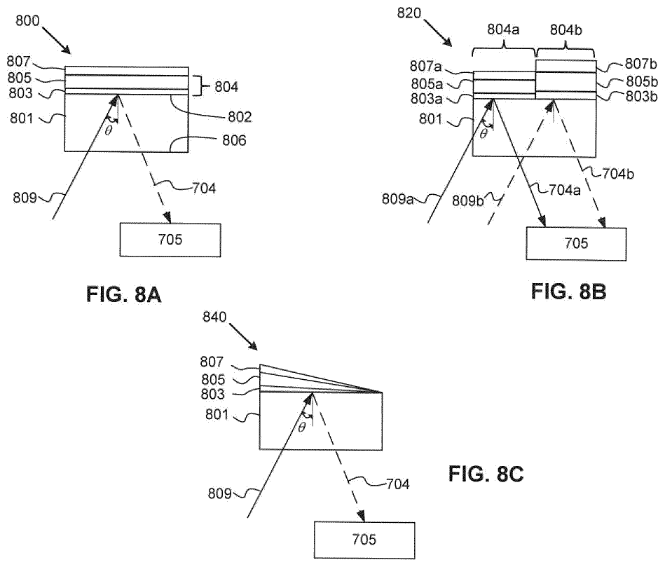

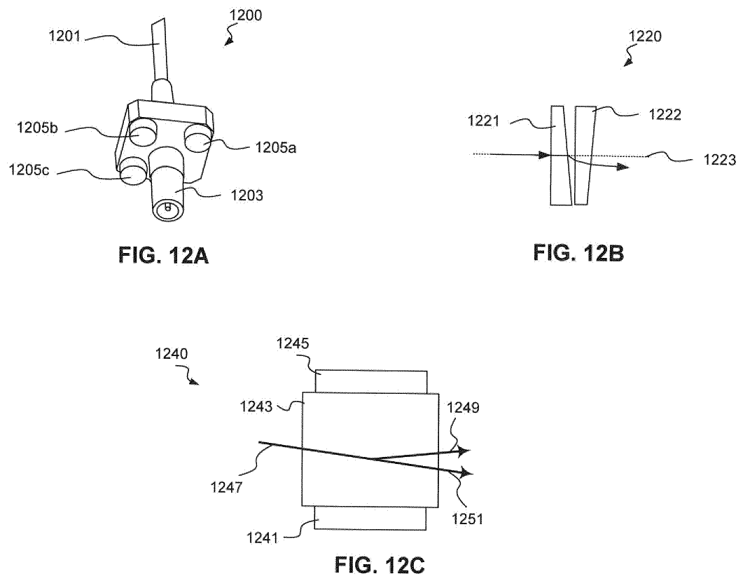

Exemplary SPR optical element 703 are discussed in more detail below with respect to FIGS. 8A-8C, 9, 10, and 11A-11C. Exemplary implementation of beam pointing compensator 701 are discussed in more detail below with respect to FIGS. 12A-12C.

### Exemplary SPR Optical Elements

As discussed above, the beam pointing monitor and compensation systems of the embodiments of this disclosure can use a surface plasmon resonance (SPR) optical element to direct radiation beam to an optical detector. The beam pointing monitor and compensation systems of the embodiments of this disclosure can utilize SPR effects to measure beam pointing deviation for calibration and correction purposes. SPR can be characterized by a loss of reflected intensity from a surface because of resonant absorption of light due to surface plasmon (SP) excitation. The beam pointing monitor and compensation systems of the embodiments of this disclosure can use SPR to determine beam pointing variation of a radiation beam with high accuracy. By measuring the beam pointing variation, the beam pointing monitor and compensation systems of the embodiments of this disclosure can correct and/or compensate for the variation within the optical system.

FIG. 8A illustrates a cross section of an SPR optical element 800 and also illustrates an optical detector 705, according to some embodiments of this disclosure. In some examples, SPR optical element 800 is similar to SPR optical element 703 of FIG. 7. In some embodiments, SPR optical element 800 can include an optical element 801. Optical element 801 can include a parallel-plane optical element or a plate optical element. For example, optical element 801 can include surfaces 802 and 806, which according to some embodiments, are parallel or substantially parallel surfaces. In some examples, surfaces 802 and 806 can be disk-shaped or substantially disk-shaped. In some examples, surfaces 802 and 806 can be rectangular or substantially rectangular. In some example, surfaces 802 and 806 can be square or substantially square. However, optical element 801 can include other configurations. According to some embodiments, optical element 801 is an optically transmissive optical element. For example, optical element 801 can be made of an optically transmissive such as, but not limited to, glass.

SPR optical element 800 can include an SPR stack 804 that supports surface plasmon resonance (SPR) on optical element 801. SPR can be characterized by a loss of reflected intensity from a surface because of resonant absorption of light due to surface plasmon (SP) excitation. In other words, the intensity of the reflected radiation beam changes compared to the intensity of the incident radiation beam depending on, for example, the incident angle of the incident radiation beam. SPR stack 804 can be provided on surface 802 of optical element 801 and can include a plurality of layers. For example, SPR stack 804 can include a metal layer 803 provided on optical element 801 and a dielectric layer 805 provided on metal layer 803. SPR optical element 801 can further include a second metal layer 807 provided on dielectric layer 805 of SPR stack 804. According to some embodiments, metal layer 807, SPR stack 804, and optical element 801, can reflect the radiation beam incident on SPR optical element 800 and support surface plasmon resonance (SPR).

According to some examples, metal layers 803 and 807 can include silver, aluminum, or other suitable metals. Dielectric layer 805 can include Silicon dioxide (SiO₂, also known as silica) or other suitable dielectric materials such as any non-absorbing dielectric material. According to some examples, metal layer 803 of SPR stack 804 can have a thickness of about 5 nm to about 40 nm. For example, metal layer 803 can have a thickness of about 10 nm to about 30 nm. In some embodiments, metal layer 807 can have a thickness of about 100 nm to about 300 nm. For example, metal layer 807 can have a thickness of about 150 nm to about 250 nm. In another example, metal layer 807 can have a thickness in the range of millimeter. According to some embodiments, dielectric layer 805 of SPR stack 804 can have a thickness of about 5 μm to about 200 μm. For example, dielectric layer 805 can have a thickness of about 10 μm to about 100 μm. In another example, dielectric layer 805 can have a thickness in the range of millimeter. However, the embodiments of this disclosure are not limited to these examples and other materials and other values for thickness can also be used.

According to some examples, the material used for layers 803, 805, and 807, the thicknesses of layers 803, 805, and 807, and the wavelength of the radiation beam incident on SPR optical element 800 can affect the sensitivity of the beam pointing monitor and compensation systems of the embodiments of this disclosure. Accordingly, the material used for layers 803, 805, and 807, the thicknesses of layers 803, 805, and 807, and the wavelength of the radiation beam incident on SPR optical element 800 can be optimized to achieve a desired sensitivity.

As illustrated in FIG. 8A, radiation beam 809 is incident on optical element 801 at an angle θ on surface 802 of optical element 801 with respect to the normal on surface 802. In some examples, radiation beam 809 can be radiation beam 702 of FIG. 7. In some examples, radiation beam 809 can be the portion of radiation beam 702 that is picked off for beam pointing monitor and compensation. Radiation beam 704 is reflected from surface 802 of optical element 801. Optical detector 705 receives the radiation beam 704 and detects the intensity of radiation beam 704. According to some embodiments, optical detector 705 can be configured to measure the intensity of the radiation beam that it receives and can include, for example, a photodiode. For example, optical detector 705 can include a PN diode or a PIN diode (e.g., a diode with an un-doped intrinsic semiconductor region between a P-type semiconductor and an N-type semiconductor region.) However, it is noted that other optical detectors can be used as optical detector 705, such as, but not limited to, CCD sensors, CMOS sensors, etc.

According to some examples, SPR optical element 800 can use one or more optical elements already used in alignment system 600 or any other systems with which beam pointing monitor and compensation system 640 is being used. For example, alignment system 600 or any other systems with which beam pointing monitor and compensation system 640 is being used can include one or more parallel-plane optical elements or plate optical elements (e.g., flat surface optical elements.) In this example, SPR stack 804 and metal layer 807 can be provided on whole or part of the one or more parallel-plane optical elements or plate optical elements in the alignment system 600 or any other systems with which beam pointing monitor and compensation system 640 is being used.

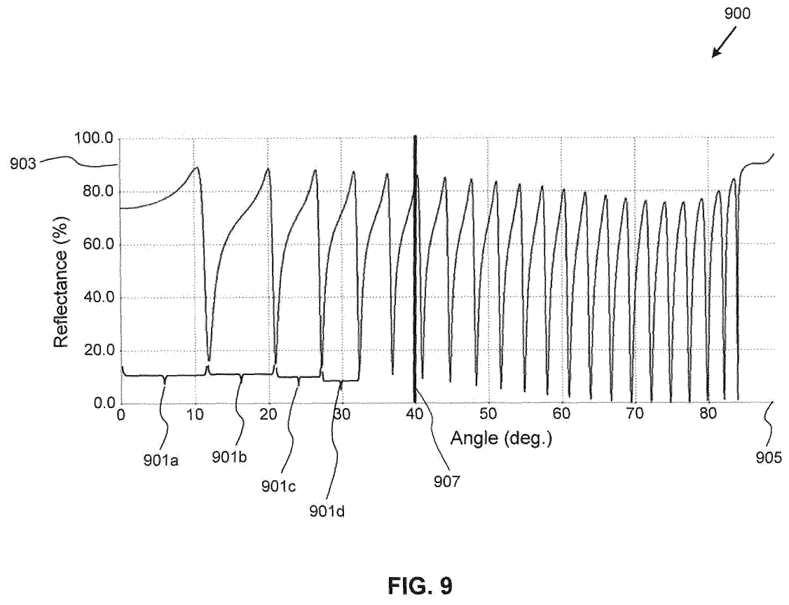

FIG. 9 schematically illustrates a plot of percent reflection as a function of incident angle for a given wavelength of incident radiation beam, according to some embodiments. Axis 903 illustrates the percent reflection and axis 905 illustrates the incident angle (e.g., angle θ of FIG. 8A.) Also, as illustrated in FIG. 9, 907 depicts the critical angle for optical element 801. The critical angle can be an angle with respect to normal to surface 802 such that radiation beams with incident angles more than the critical angle will reflect entirely from surface 802 (e.g., the boundary between optical element 801 and SPR stack 804.) In other words, total internal reflection occurs for radiation beams with incident angles more than the critical angle.

Plot 900 illustrates a resonance of the percent reflection as a function of angle. The resonance can occur in a shape of a comb of notches as the function of angle. For example, plot 900 illustrates notches 901a, 901b, 901c, 901d, etc. As illustrated in plot 900, the resonance is a variable resonance. In other words, the width of notches 901a, 901b, 901c, 901d, etc. changes when the angle changes from 0 degrees to 90 degrees. Also, as illustrated in FIG. 9, plot 900 includes notches for angles smaller than the critical angle 907 and notches for angles greater than critical angle 907.

By measuring the intensity of the reflected radiation beam 704, optical detector 705 (alone, or in combination with signal analyzer 630) can be configured to determine the angle of incidence of radiation beam 809 (e.g., angle θ of FIG. 8A.) According to some embodiments, SPR optical element 800 can be used for a coarse measurement of the incident angle of radiation beam 809. Additionally or alternatively, SPR optical element 800 can be used for a fine measurement of the incident angle of radiation beam 809. For example, by knowing on which notch the measured intensity of reflected radiation beam 704 is, optical detector 705 (alone, or in combination with signal analyzer 630) can more accurately determine the incident angle of radiation beam 809.

According to some embodiments, the beam pointing monitor and compensation systems of this disclosure are configured to measure beam pointing variations and compensate for the variations for any angle of incidence (e.g., angle θ of FIG. 8A) of the radiation beams. In other words, the beam pointing monitor and compensation systems of this disclosure are not dependent on total internal reflection (TIR) of the beam pointing monitor systems, according to some embodiments. Therefore, the beam pointing monitor and compensation systems of this disclosure can measure beam pointing variations (and compensate for the variations) for angles of incident of the radiation beams that are smaller than a critical angle of the beam pointing monitor systems.

The sensitivity of the beam pointing measurement systems of the embodiments of this disclosure can be determined by the material used for the layers of SPR stack 804 and metal layer 807, the thicknesses of the layers of SPR stack 804 and metal layer 807, and/or the wavelength of the radiation beam 809. For example, the number, the width, and/or the depth of notches 901a, 901b, 901c, 901d, etc. can be controlled based on the material used for the layers of SPR stack 804 and metal layer 807, the thicknesses of the layers of SPR stack 804 and metal layer 807, and/or the wavelength of the radiation beam 809.

According to one example, the material and/or the thickness of metal layer 803 can control the depth (e.g., the distance along axis 903 between the maximum and minimum points on each notch) of notches 901a, 901b, 901c, 901d, etc. In this example, the material and/or the thickness of metal layer 803 can be tuned to achieve predetermined depths for notches 901a, 901b, 901c, 901d, etc. According to one example, the material and/or the thickness of dielectric layer 805 can control the width (e.g., the distance along axis 905 between the maximum and minimum points on each notch) of notches 901a, 901b, 901c, 901d, etc. In this example, the material and/or the thickness of dielectric layer 805 can be tuned to achieve predetermined widths for notches 901a, 901b, 901c, 901d, etc. For example, by choosing a thick dielectric layer 805, the widths of notches 901a, 901b, 901c, 901d, etc. can be made small, and therefore, achieve a more sensitive beam pointing monitor system.

According to some examples, the width, and/or the depth of notches 901a, 901b, 901c, 901d, etc. can depend on the wavelength of the radiation beam. In some examples, radiation beam 809 can include two or more wavelengths. SPR optical element 800 and optical detector 705 can use the two or more wavelengths for beam pointing measurements. For example, SPR optical element 800 and optical detector 705 can use one wavelength of radiation beam 809 (a wavelength that has notches 901a, 901b, 901c, 901d, etc. with larger width) for coarse measurement and use another wavelength of radiation beam 809 (a wavelength that has notches 901a, 901b, 901c, 901d, etc. with smaller width) for fine measurement. Additionally or alternatively, SPR optical element 800 and optical detector 705 can use a combination of the detected radiation of the two wavelengths for beam pointing measurements.

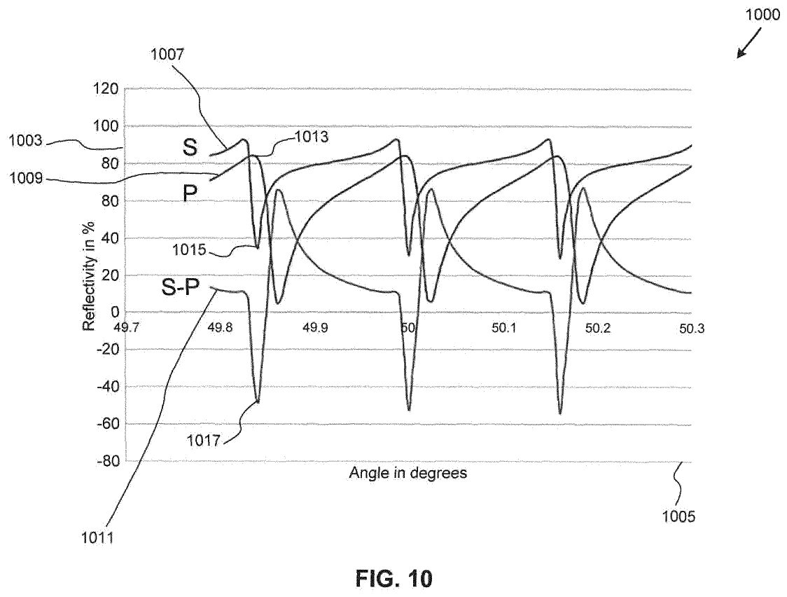

FIG. 10 schematically illustrates a plot of percent reflection as a function of incident angle for a given wavelength of incident radiation beam, according to some embodiments. Axis 1003 illustrates the percent reflection and axis 1005 illustrates the incident angle. Plot 1000 illustrates the resonance of the percent reflection as a function of angle for a radiation with S polarization orientation (plot 1007), for a radiation with P polarization orientation (plot 1009), and for a difference between the S and P polarization orientations (plot 1011). As illustrated in plot 1000, SPR optical element 800 can be designed such that the maximum at each notch of plot 1009 (e.g., point 1013) be substantially aligned with the minimum of the corresponding notch of plot 1007 (e.g., point 1015) such that the depth 1017 of plot 1011 is increased compared to plots 1007 and 1009. Accordingly, the depth of plot 1011 can be increased and therefore, the sensitivity of SPR optical element 800 can be increased.

According to some examples, one or more SPR optical elements and one or more optical detectors can be used to receive radiation beams with S polarization orientation and P polarization orientation. The one or more SPR optical elements and one or more optical detectors can be configured to measure the intensity of the radiation beams with S polarization orientation and P polarization orientation and can be configure to use (alone or with signal analyzer 630), for example, plot 1000 of FIG. 10 to determine the angle of incidence for the radiation beam with S polarization orientation and/or radiation beam with P polarization orientation.

According to some examples, SPR optical element 800 with optical sensor 705 can be a spatially-distributed beam pointing monitor system. In this example, optical detector 705 can include a photodiode array, therefore, detecting various spatially-distributed sensor responses across surface 802 of SPR optical element 800. According to some embodiments, an optical polarizing element (not shown) can be included between SPR optical element 800 and optical detector 705. The photodiode array of the optical detector 705 can detect various spatially-distributed sensor responses across surface 802 of SPR optical element 800. In this example, SPR stack 804 of SPR optical element 800 can include a spatial-distributed SPR stack surface pattern. Different subsections of the patterned area can be formed with unique functionality. In this example, the spatially-distributed beam pointing measurement system with combined functionality can be addressed by interrogating individual subsections of the patterned area surface. As one example, adjacent subsections may be devised to detect increasingly larger or smaller nominal beam angles of incidence. For example, SPR stack 804 can be configured as at least one of laterally defined or patterned such that subsections of SPR stack 804 can act independently as a function of position. Thus, a selectable range of incident beam angle could be analyzed.

According to some examples, SPR optical element 800 with optical sensor 705 can be an electro-optically addressable beam pointing monitor system. In this example, SPR stack 804 of SPR optical element 800 can include an electro-optically addressable element, including, for example, an electro-optic surface plasmon resonance (SPR) stack. The electro-optic SPR stack can include at least one of a patterned electro-optic coating for providing a dielectric layer or a segmented and addressable spatially electro-optic coating. In this example, optical detector 705 can include a photodiode array, thus detecting various spatially-distributed sensor responses across SPR optical element 800 in response to an electronic input of a voltage V at terminals (not shown) connected to SPR stack 804.

According to some examples, the electro-optic SPR stack can be a segmented electro-optically addressable SPR stack. In this example, SPR stack 804 can have a spatial-distributed SPR stack surface pattern. Different subsections of a patterned area may be formed with unique functionality. In this example, optical detector 705 can include a photodiode array, thus detecting various spatially-distributed sensor responses across SPR optical element 800 in response to an electronic input of a voltage V at terminals (not shown) connected to SPR stack 804. In this example, each subsection of the patterned area of the electro-optic SPR stack can have its respective terminals and be controlled independently of the other subsections of the patterned area of the electro-optic SPR stack.

FIG. 8B illustrates an SPR optical element 820 and an optical detector 705, according to some embodiments of this disclosure. In some embodiments, SPR optical element 820 can include an optical element 801, which can include a parallel-plane optical element or a plate optical element. According to some embodiments, optical element 801 is an optically transmissive optical element. SPR optical element 820 can include a stepped SPR stack that supports surface plasmon resonance (SPR) on optical element 801. For example, the stepped SPR stack can include a first SPR stack 804a and a second SPR stack 804b.

For example, SPR stack 804a can include a metal layer 803a provided on optical element 801 and a dielectric layer 805a provided on metal layer 803a. A second metal layer 807a can be provided on dielectric layer 805a. SPR stack 804b can include a metal layer 803b provided on optical element 801 and a dielectric layer 805b provided on metal layer 803b. A second metal layer 807b can be provided on dielectric layer 805b. The incident radiation beam 809a (or 809b) can be scanned across different thicknesses of the stepped SPR stack to detect various angles and ranges of angle of the incident radiation beam.

Although only two SPR stacks 804a and 804b are illustrated, the stepped SPR stack can include any number of portions. Also, FIG. 8B illustrates that metal layers 803a and 803b have different thicknesses, dielectric layers 805a and 805b have different layers, and metal layers 807a and 807b have different thickness. However, the embodiments of this disclosure are not limited to this example. For example, metal layers 803a and 803b can have same or substantially same thicknesses but layers 805a and 805b can have different thicknesses and/or layers 807a and 807b can have different thicknesses. For example, metal layers 803a and 803b can have same or substantially same thicknesses, metal layers 807a and 807b can have same or substantially same thicknesses, but dielectric layers 805a and 805b can have different thicknesses. In other words, the thicknesses of layers 803a, 805a, and 807a and the thicknesses of layers 803b, 805b, and 807b can be designed such that SPR stacks 804a and 804b result in a stepped SPR stack.

FIG. 8C illustrates an SPR optical element 840 and an optical detector 705, according to some embodiments of this disclosure. In some embodiments, SPR optical element 840 can include an optical element 801, which can include a parallel-plane optical element or a plate optical element. According to some embodiments, optical element 801 is an optically transmissive optical element. SPR optical element 840 can include a wedged SPR stack that supports surface plasmon resonance (SPR) on optical element 801.

For example, the wedged SPR stack can include a metal layer 803 provided on optical element 801 and a dielectric layer 805 provided on metal layer 803. A second metal layer 807 can be provided on dielectric layer 805. The incident radiation beam 809 can be scanned across different thicknesses of the wedged SPR stack to detect various angles and ranges of angle of the incident radiation beam. Scanning of areas of different wedge thicknesses can allow for a single optical detector to act as a variable angle range detector.

FIG. 8C illustrates the wedged SPR stack where each layer 803 and 805 is wedged. FIG. 8C illustrates that second metal layer 807 is also wedged. However, the embodiments of this disclosure are not limited to this example. For example, one or more layers of the wedged SPR stack and/or second metal layer 807 can be substantially parallel-plane plates (e.g., not wedged.) For example, in some embodiments, dielectric layer 805 and second metal layer 807 can be wedged while metal layer 803 is not wedged (e.g., substantially parallel-plane plates.) As another example, dielectric layer 805 can be wedged, while metal layers 803 and 805 are not wedged (e.g., substantially parallel-plane plates).

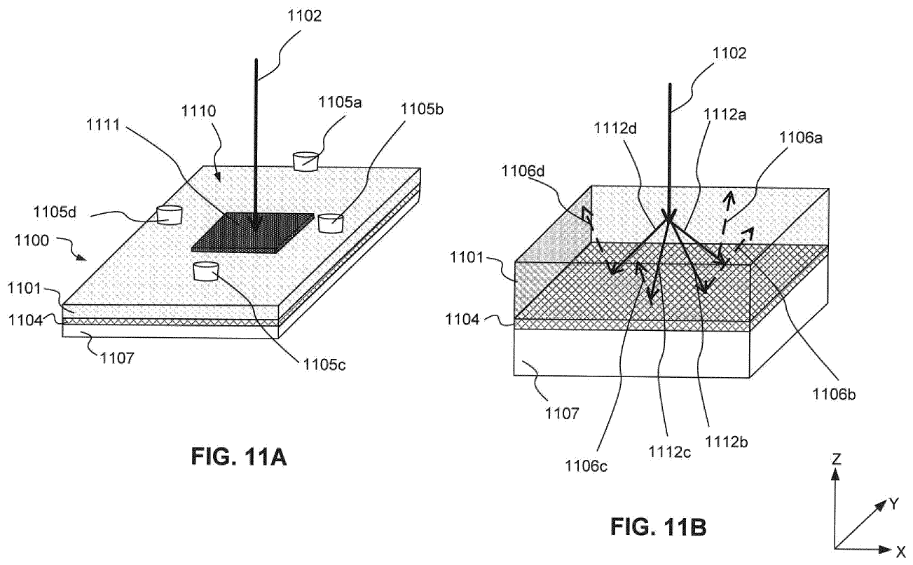

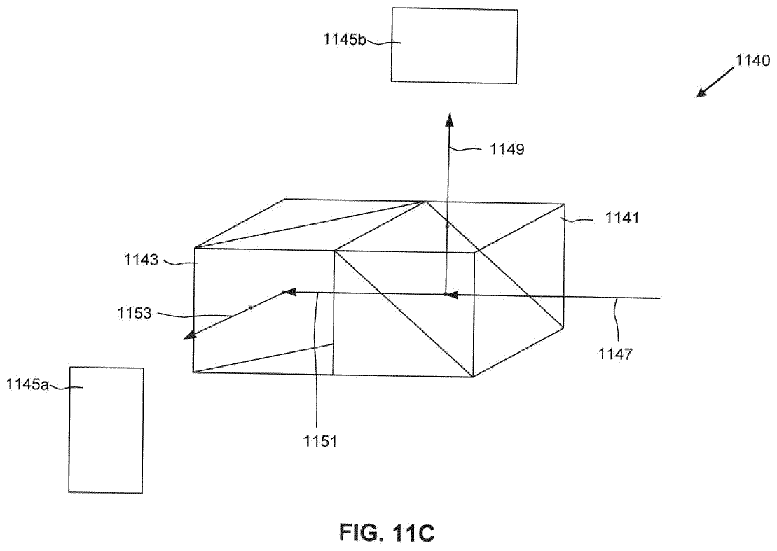

FIGS. 11A and 11B illustrate exemplary SPR optical elements according to some embodiments. FIG. 11A illustrates SPR optical element 1100 with a grating 1111. According to some examples, grating 1111 can be an X-Y diffraction grating. However, the embodiments of this disclosure are not limited to this example and other types of gratings can be provided. According to some embodiments, grating 1111 is provided on surface 1110 of optical element 1101 of SPR optical element 1100 and is configured to receive the radiation beam 1102. SPR optical element 1100 includes optical element 1101, SPR stack 1104 (which can include a metal layer and a dielectric layer), and metal layer 1107, according to some embodiments. SPR optical element 1100 can be similar to SPR optical elements 800, 820, and 840 of FIGS. 8A-C.

FIG. 11A also illustrates four optical detectors 1105a-1105d configured to receive reflected radiation beams from SPR optical element 1100. Exemplary operation of SPR optical element 1100 with grating 1111 is discussed with respect to FIGS. 11A and 11B. Incident radiation beam 1102 is incident on grating 1111 (not shown in FIG. 11B). According to some examples, grating 1111 can be configured to diffract radiation beam 1102 to two more diffracted radiation beams 1112a-1112d. According to some examples, diffracted radiation beams 1112a and 1112c are diffracted along the Y-axis direction. Diffracted radiation beams 1112b and 1112d are diffracted along the X-axis direction. In some examples, the angle of diffraction of the diffracted radiation beams 1112a-1112d can depend on the structure of grating 1111, such as the pitch of grating 11111. Diffracted radiation beams 1112a-1112d are reflected from SPR optical element 1100. Reflected radiation beams 1106a-1106d are received by optical detectors 1105a-1105d. Optical detectors 1105a-1105d (alone or in combination with signal analyzer 630) are configured to determine the angle of incidence of diffracted radiation beams 1112a-1112d, and therefore, the angle of incidence of radiation beam 1102.

According to some examples, optical detectors 1105a-1105d (alone or in combination with signal analyzer 630) can use a difference between measured intensities of radiation beams 1106b and 1106d and a difference between measured intensities of radiation beams 1106a and 1106c to determine the angle of incidence of radiation beam 1102.

FIG. 11C illustrates another beam pointing monitor and compensation system, according to some embodiments. In this example, system 1140 can include two beam pointing monitor systems 1145a and 1145b. Each of beam pointing monitor systems 1145a and 1145b can include an SPR optical element and an optical detector, according to some embodiments. In the exemplary system 1140, beam pointing monitor system 1145a can be configured to measure beam pointing along, for example, X direction using a radiation beam with S polarization orientation. Also, beam pointing monitor system 1145b can be configured to measure beam pointing along, for example, Y direction using a radiation beam with P polarization orientation.

In this example, radiation beam 1147 is incident on polarizing beam splitter 1141. According to some examples radiation beam 1147 can be a non-polarized radiation beam. Additionally or alternatively, radiation beam 1147 can include different polarization information. Radiation beam 1147 is divided into sub-beams 1149 and 1151. Sub-beam 1149, which is reflected from polarizing beam splitter 1141 can have S polarization orientation, according to some examples. Sub-beam 1151, which is passed through polarizing beam splitter 1141 can have P polarization orientation, according to some examples. Sub-beam 1151 can further enter beam splitter 1143 and be reflected as radiation beam 1153 with P polarization orientation. According to some examples, beam splitter 1143 is a polarizing beam splitter. Alternatively, beam splitter 1143 can be a non-polarizing beam splitter.

According to some examples, beam pointing monitor system 1145a can be configured to receive radiation beam 1149 and measure beam pointing of radiation beam 1149 along, for example, X direction using radiation beam 1149 with S polarization orientation. According to some examples, beam pointing monitor system 1145b can be configured to receive radiation beam 1153 and measure beam pointing of radiation beam 1153 along, for example, Y direction using radiation beam 1153 with P polarization orientation. Additionally, beam pointing monitor systems 1145a and 1145b, alone or in combination with, for example, signal analyzer 630, can be configured to measure beam pointing of radiation beam 1147 along, for example, X and Y direction based on the measurements of radiation beams 1149 and 1153.

FIGS. 12A-C illustrate exemplary beam pointing compensators, according to some embodiments. The beam pointing compensators of FIGS. 12A-C can be used as beam pointing compensator 701 of FIG. 7, in some embodiments.

FIG. 12A illustrates an input fiber assembly 1200, which can be used for beam pointing compensation. According to some examples, input fiber assembly 1200 can include a first portion 1201 that can be coupled to fiber optics to receive a radiation beam. The input fiber assembly 1200 can also include a second portion 1203 configured to output the radiation beam. According to some embodiments, input fiber assembly 1200 can include actuators 1205a-1205c to control the beam pointing of the radiation beam coming out of second portion 1203. Although three actuators 1205a-1205c are illustrated, input fiber assembly 1200 can include any number (one or more) actuators. According to some examples, actuators 1205a-1205c can include one or more actuator screws, one or more piezoelectric actuators, or any other actuators configured to control input fiber assembly 1200. Actuators 1205a-1205c can receive, for example, control signal 708 of FIG. 7 from signal analyzer 630 based on the measured beam pointing deviation and control input fiber assembly 1200 to compensate for the measured deviation.

Beam pointing compensators used in the embodiments of this disclosure can also include opto-mechanical adjustable compensators. For example, beam pointing compensators can include one or more prisms, one or more mirrors, one or more wedges, or other opto-mechanical adjustable compensators configured to correct/compensate for measured beam pointing deviations. For example, FIG. 12B illustrates on exemplary opto-mechanical adjustable compensator 1220 including wedge prisms 1221 and 1222. According to some examples, wedge prims 1221 and 1222 can receive, for example, control signal 708 of FIG. 7 from signal analyzer 630 based on the measured beam pointing deviation and control opto-mechanical adjustable compensator 1220 to compensate for the measured deviation. The compensation can occur by rotating wedge prims 1221 and 1222 along the rotation axis 1223 independently of each other. According to some examples, one wedge prism can be used to change an angle of incidence based on the measure beam pointing deviation.

Beam pointing compensators used in the embodiments of this disclosure can also include electro-optic compensators. For example, beam pointing compensators can include one or more electro-optic cells, one or more acousto-optic beam deflectors, or other electro-optic compensators configured to correct/compensate for measured beam pointing deviations. For example, FIG. 12C illustrates on exemplary acousto-optic beam deflector 1240 including transducer 1241, a medium 1243, and an acoustic absorber 1245. According to some examples, transducer 1241 is configured to generate sound waves within medium 1243. The sound waves can travel from transducer 1241 toward acoustic absorber 1245. Radiation beam 1247 is incident on medium 1243. Medium 1243 and the sound waves within medium 1243 can act as a grating that diffracts radiation beam 1247 into diffracted radiation beam 1249 and transmitted radiation beam 1251. The acoustic wavelength of the sound waves within medium 1243 can control the angle of the diffracted radiation beam 1249. The wavelength of the sound waves within medium 1243 can be controlled with a signal to transducer 1241. Additionally or alternatively, the wavelength of the sound waves within medium 1243 can be controlled by controlling medium 1243 (e.g., controlling the length, the width, etc. of medium 1243.) Transducer 1241 can receive, for example, control signal 708 of FIG. 7 from signal analyzer 630 based on the measured beam pointing deviation and control acousto-optic beam deflector 1240 to compensate for the measured deviation. The compensation can occur by controlling the wavelength of the sound waves within medium 1243.

Although some exemplary systems are shown as exemplary embodiments for beam pointing compensator 701, the embodiments of this disclosure are not limited to these examples. Other suitable beam pointing compensators can be used in the embodiments of this disclosure to receive control signals based on beam pointing deviations and to compensate for the deviations.

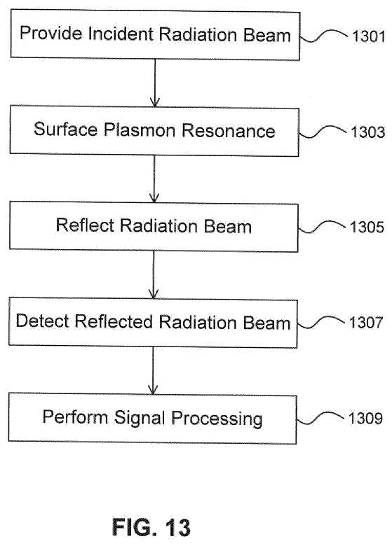

FIG. 13 is a flowchart depicting a method 1300, according to an embodiment. For example, method 1300 can measure beam pointing variations, according to some embodiments. In one example, method 1300 is performed by beam pointing monitor and compensation system 640. It is to be appreciated not all steps may be needed, and the steps may not be performed in the same order as shown in FIG. 13. Reference is made to beam pointing monitor and compensation system 640 of FIGS. 6 and 7 and SPR optical element 800 and optical detector 750 FIG. 8A merely for convenience of discussion. Other systems may be used to perform the method as will be understood by those skilled in the arts.

At 1301, an incident radiation beam, such as radiation beam 809 is provided to SPR optical element 800. At 1303, a surface plasmon resonance is provided using, for example, SPR stack 804. At 1305, radiation beam 704 is reflected from SPR optical element 800. The reflected radiation beam 704 is a SPR reflected radiation beam, according to some examples. At 1307, optical detector 705 receives the reflected radiation beam 704 and measures, for example, the intensity of the reflected radiation beam 704 and/or a percentage of reflectance of the reflected radiation beam 704. At 1309, based on the measured intensity of the reflected radiation beam 704 and/or the measured percentage of reflectance of the reflected radiation beam 704, optical detector 705, alone or in combination with signal analyzer 630, determines the angle of incidence (e.g., beam pointing) of radiation beam 809. Signal analyzer 630, alone or in combination with optical detector 705, determines a beam pointing variation by, for example, comparing the measured angle of incidence and a reference angle of incidence. According to some embodiments, the reference angle of incidence is stored in a memory (not shown) accessible by signal analyzer 630.

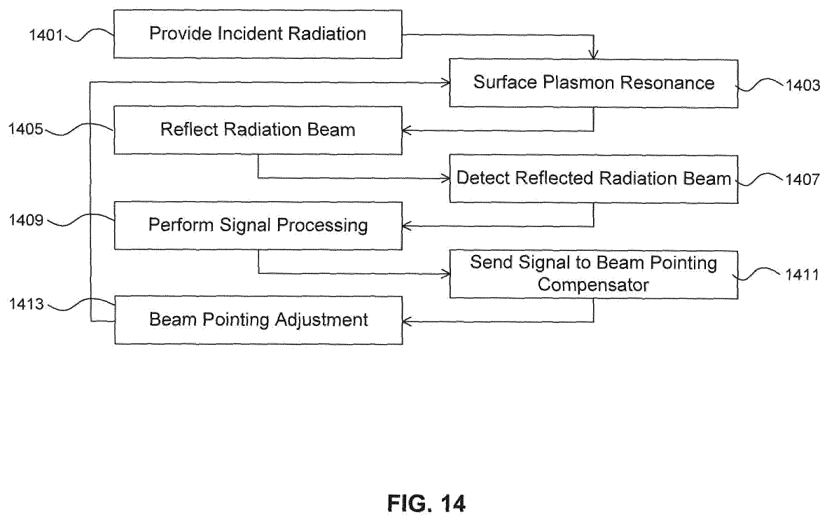

FIG. 14 is a flowchart depicting a method 1400, according to an embodiment. For example, method 1400 can measure beam pointing variations and compensate for the variations, according to some embodiments. In one example, method 1400 is performed by beam pointing monitor and compensation system 640. It is to be appreciated not all steps may be needed, and the steps may not be performed in the same order as shown in FIG. 14. Reference is made to beam pointing monitor and compensation system 640 of FIGS. 6 and 7 and SPR optical element 800 and optical detector 705 FIG. 8A merely for convenience of discussion. Other systems may be used to perform the method as will be understood by those skilled in the arts.

Steps 1401-1409 of method 1400 are similar to steps 1301-1309 of method 1300. For example, at 1401, an incident radiation beam, such as radiation beam 809 is provided to SPR optical element 800. At 1403, a surface plasmon resonance is provided using, for example, SPR stack 804. At 1405, radiation beam 704 is reflected from SPR optical element 800. The reflected radiation beam 704 is a SPR reflected radiation beam, according to some examples. At 1407, optical detector 705 receives the reflected radiation beam 704 and measures, for example, intensity of the reflected radiation beam 704 and/or a percentage of reflectance of the reflected radiation beam 704. At 1409, based on the measured intensity of the reflected radiation beam 704 and/or the measured percentage of reflectance of the reflected radiation beam 704, optical detector 705, alone or in combination with signal analyzer 630, determines the angle of incidence (e.g., beam pointing) of radiation beam 809. Signal analyzer 630, alone or in combination with optical detector 705, determines a beam pointing variation by, for example, comparing the measured angle of incidence and a reference angle of incidence.

At 1411, signal analyzer 630, as one example, sends a control signal (e.g., control signal 708 of FIG. 7) to beam pointing compensator 701. At 1413, beam pointing compensator 701, based on the received control signal, adjusts the angle of incidence (e.g., beam pointing) of, for example, radiation beam 641, which will be provided to SPR optical element 800. Method 1400 can continue with steps 1403-1413 to measure any beam pointing variation based on the adjusted beam pointing and, if needed, to further adjust the beam pointing.

The embodiments may further be described using the following clauses:
1. A beam pointing monitor and compensation system, comprising:
   a surface plasmon resonance (SPR) optical element, comprising:
   an optical element comprising first and second surfaces, wherein the first and second surfaces are substantially parallel to each other;
   a first metal layer provided on the second surface of the optical element;
   a dielectric layer provided on the first metal layer; and
   a second metal layer provided on the dielectric layer.
2. The beam pointing monitor and compensation system of clause 1, wherein the optical element comprises an optically transmissive material.
3. The beam pointing monitor and compensation system of clause 1, wherein the SPR optical element is configured to receive a radiation beam and provide a SPR reflected radiation beam.
4. The beam pointing monitor and compensation system of clause 3, further comprising:
   an optical detector configured to receive the SPR reflected radiation beam and to measure an intensity of the received SPR reflected radiation beam.
5. The beam pointing monitor and compensation system of clause 3, further comprising:
   a beam pointing compensator configured to control an angle of incidence of the radiation beam on the SPR optical element.
6. The beam pointing monitor and compensation system of clause 5, wherein:
   the beam pointing compensator is configured to receive a control signal to control the angle of incidence of the radiation beam on the SPR optical element, and
   the control signal is determined based on a measurement of the angle of incidence.
7. A system comprising:
   an illumination system configured to provide a radiation beam; and
   a beam pointing monitor system, comprising:
      a surface plasmon resonance (SPR) optical element, comprising:
         an optical element comprising first and second surfaces, wherein the first and second surfaces are substantially parallel to each other;
         a first metal layer provided on the second surface of the optical element;
         a dielectric layer provided on the first metal layer; and
         a second metal layer provided on the dielectric layer,
   wherein the beam pointing monitor system is configured to measure an angle of incidence of the radiation beam with respect to a normal to the second surface of the optical element.
8. The system of clause 7, wherein:
   the optical element comprises an optically transmissive material, and
   the SPR optical element is configured to receive a radiation beam and to provide an SPR reflected radiation beam.
9. The system of clause 8, wherein the beam pointing monitor system further comprises an optical detector configured to receive the SPR reflected radiation beam and to measure an intensity of the received SPR reflected radiation beam.
10. The system of clause 8, further comprising:
   a beam pointing compensator configured to control the angle of incidence of the radiation beam on the SPR optical element,
   wherein the beam pointing compensator is configured to receive a control signal to control the angle of incidence of the radiation beam on the SPR optical element, the control signal is determined based on a measurement of the angle of incidence, and the measurement of the angle of incidence is determined based on the measured intensity of the received SPR reflected radiation beam.
11. A method comprising:
   illuminating, with a radiation beam, a surface plasmon resonance (SPR) optical element, wherein the radiation beam is incident on the SPR optical element at an angle of incidence with respect to a normal to the SPR optical element, and the SPR optical element comprises an optical element comprising first and second surfaces, the first and second surfaces being substantially parallel to each other;
   detecting, using a detector, a reflected radiation beam reflected from the SPR optical element, wherein the SPR optical element provides a SPR of the reflected radiation beam;
   measuring an intensity of the reflected radiation beam; and
   determining the angle of incidence.
12. The method of clause 11, further comprising:
   transmitting a control signal to a beam pointing compensator configured to adjust the angle of incidence.
13. The method of clause 11, further comprising:
   adjusting, using a beam pointing compensator, the angle of incidence based on the control signal.
14. An alignment system comprising:
   an illumination system configured to provide a radiation beam;
   a beam pointing monitor configured to measure an angle of incidence of the radiation beam with respect to a normal to a surface of the beam pointing monitor and to determine a beam pointing variation; and
   a beam pointing compensator configured to receive a control signal based on the determined beam pointing variation and to adjust the angle of incidence of the radiation beam.
15. The alignment system of clause 14, wherein the beam pointing monitor comprises a surface plasmon resonance (SPR) optical element, the SPR optical element comprising:
   an optical element comprising first and second surfaces, wherein the first and second surfaces are substantially parallel to each other;
   a first metal layer provided on the second surface of the optical element;
   a dielectric layer provided on the first metal layer; and
   a second metal layer provided on the dielectric layer.
16. The alignment system of clause 15, wherein the optical element comprises an optically transmissive material.
17. The alignment system of clause 15, wherein the SPR optical element is configured to receive a radiation beam and provide a surface plasmon resonance (SPR) reflected radiation beam.
18. The alignment system of clause 17, further comprising:
   an optical detector configured to receive the SPR reflected radiation beam and to measure an intensity of the received SPR reflected radiation beam.
19. A lithographic apparatus comprising:
   a first illumination system configured to illuminate a pattern of a patterning device;
   a projection system configured to project an image of the pattern on to a target portion of a substrate; and
   a system comprising:
      a second illumination system configured to provide a radiation beam; and
      a beam pointing monitor and compensation system, comprising:
         a surface plasmon resonance (SPR) optical element, comprising:
            an optical element comprising first and second surfaces;
            a first metal layer provided on the second surface of the optical element;
            a dielectric layer provided on the first metal layer; and
            a second metal layer provided on the dielectric layer,
      wherein the beam pointing monitor and compensation system is configured to measure an angle of incidence of the radiation beam with respect to a normal to the second surface of the optical element.
20. The lithographic apparatus of clause 19, wherein the first and second surfaces of the optical element are substantially parallel to each other.

Although specific reference may have been made above to the use of embodiments of the disclosure in the context of optical lithography, it will be appreciated that the disclosure may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams. As mentioned above, the term radiation in the context of the driving system may also encompass microwave radiation.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present disclosure should not be limited by any of the above-described exemplary embodiments, but should be defined only in accordance with the following claims and their equivalents.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

What is claimed is:

1. A beam pointing monitor and compensation system, comprising:
a surface plasmon resonance (SPR) optical element, comprising:
an optical element comprising first and second surfaces, wherein the first and second surfaces are substantially parallel to each other;
a first metal layer provided on the second surface of the optical element;
a dielectric layer provided on the first metal layer; and
a second metal layer provided on the dielectric layer.

2. The beam pointing monitor and compensation system of claim 1, wherein the optical element comprises an optically transmissive material.

3. The beam pointing monitor and compensation system of claim 1, wherein the SPR optical element is configured to receive a radiation beam and provide a SPR reflected radiation beam.

4. The beam pointing monitor and compensation system of claim 3, further comprising:
an optical detector configured to receive the SPR reflected radiation beam and to measure an intensity of the received SPR reflected radiation beam.

5. The beam pointing monitor and compensation system of claim 3, further comprising:
a beam pointing compensator configured to control an angle of incidence of the radiation beam on the SPR optical element.

6. The beam pointing monitor and compensation system of claim 5, wherein:
the beam pointing compensator is configured to receive a control signal to control the angle of incidence of the radiation beam on the SPR optical element, and
the control signal is determined based on a measurement of the angle of incidence.

7. A system comprising:
an illumination system configured to provide a radiation beam; and
a beam pointing monitor system, comprising:
a surface plasmon resonance (SPR) optical element, comprising:
an optical element comprising first and second surfaces, wherein the first and second surfaces are substantially parallel to each other;
a first metal layer provided on the second surface of the optical element;
a dielectric layer provided on the first metal layer; and
a second metal layer provided on the dielectric layer,
wherein the beam pointing monitor system is configured to measure an angle of incidence of the radiation beam with respect to a normal to the second surface of the optical element.

8. The system of claim 7, wherein:
the optical element comprises an optically transmissive material, and
the SPR optical element is configured to receive a radiation beam and to provide an SPR reflected radiation beam.

9. The system of claim 8, wherein the beam pointing monitor system further comprises an optical detector configured to receive the SPR reflected radiation beam and to measure an intensity of the received SPR reflected radiation beam.

10. The system of claim 8, further comprising:
a beam pointing compensator configured to control the angle of incidence of the radiation beam on the SPR optical element,
wherein the beam pointing compensator is configured to receive a control signal to control the angle of incidence of the radiation beam on the SPR optical element, the control signal is determined based on a measurement of the angle of incidence, and the measurement of the angle of incidence is determined based on the measured intensity of the received SPR reflected radiation beam.

11. A method comprising:
illuminating, with a radiation beam, a surface plasmon resonance (SPR) optical element, wherein the radiation beam is incident on the SPR optical element at an angle of incidence with respect to a normal to the SPR optical element, and the SPR optical element comprises an optical element comprising first and second surfaces, the first and second surfaces being substantially parallel to each other;
detecting, using a detector, a reflected radiation beam reflected from the SPR optical element, wherein the SPR optical element provides a SPR of the reflected radiation beam;
measuring an intensity of the reflected radiation beam; and
determining the angle of incidence.

12. The method of claim 11, further comprising:
transmitting a control signal to a beam pointing compensator configured to adjust the angle of incidence.

13. The method of claim 11, further comprising:
adjusting, using a beam pointing compensator, the angle of incidence based on the control signal.

14. An alignment system comprising:
an illumination system configured to provide a radiation beam;
a beam pointing monitor configured to measure an angle of incidence of the radiation beam with respect to a normal to a surface of the beam pointing monitor and to determine a beam pointing variation; and
a beam pointing compensator configured to receive a control signal based on the determined beam pointing variation and to adjust the angle of incidence of the radiation beam.

15. The alignment system of claim 14, wherein the beam pointing monitor comprises a surface plasmon resonance (SPR) optical element, the SPR optical element comprising:
an optical element comprising first and second surfaces, wherein the first and second surfaces are substantially parallel to each other;
a first metal layer provided on the second surface of the optical element;
a dielectric layer provided on the first metal layer; and
a second metal layer provided on the dielectric layer.

16. The alignment system of claim 15, wherein the optical element comprises an optically transmissive material.

17. The alignment system of claim 15, wherein the SPR optical element is configured to receive a radiation beam and provide a surface plasmon resonance (SPR) reflected radiation beam.

18. The alignment system of claim 17, further comprising:
an optical detector configured to receive the SPR reflected radiation beam and to measure an intensity of the received SPR reflected radiation beam.

19. A lithographic apparatus comprising:
a first illumination system configured to illuminate a pattern of a patterning device;
a projection system configured to project an image of the pattern on to a target portion of a substrate; and
a system comprising:
a second illumination system configured to provide a radiation beam; and
a beam pointing monitor and compensation system, comprising:
a surface plasmon resonance (SPR) optical element, comprising:
an optical element comprising first and second surfaces;
a first metal layer provided on the second surface of the optical element;
a dielectric layer provided on the first metal layer; and
a second metal layer provided on the dielectric layer,
wherein the beam pointing monitor and compensation system is configured to measure an angle of incidence of the radiation beam with respect to a normal to the second surface of the optical element.

20. The lithographic apparatus of claim 19, wherein the first and second surfaces of the optical element are substantially parallel to each other.
